(19) United States
(12) Patent Application Publication
(10) Pub. No.: US 2009/0294761 A1
(43) Pub. Date: Dec. 3, 2009

(54) ORGANIC PHOTOELECTRIC CONVERSION FILM, AND PHOTOELECTRIC CONVERSION DEVICE AND IMAGE SENSOR EACH HAVING THE ORGANIC PHOTOELECTRIC CONVERSION FILM

(75) Inventors: Kyu-sik KIM, Yongin-si (KR); Sang-cheol PARK, Seoul (KR); Jung-gyu NAM, Suwon-si (KR); Masahiro HIRAMOTO, Osaka (JP)

Correspondence Address: CANTOR COLBURN, LLP, 20 Church Street, 22nd Floor, Hartford, CT, 06103, US

(73) Assignees: SAMSUNG ELECTRONICS CO., LTD., Suwon-si (KR); OSAKA UNIVERSITY, Osaka (JP)

(21) Appl. No.: 12/238,857

(22) Filed: Sep. 26, 2008

(30) Foreign Application Priority Data
May 28, 2008 (KR) 10-2008-0049678

(51) Int. Cl. H01L 51/30

(52) U.S. Cl. 257/40; 257/E51.026

(57) ABSTRACT

Provided are an organic photoelectric conversion film, and a photoelectric conversion device and an image sensor each having the organic photoelectric conversion film. The organic photoelectric conversion film includes a p-type material layer formed of an organic material; and a n-type material layer formed on the p-type material layer, the n-type material being formed from naphthalene-1,4,5,8-tetracarboxylic dianhydride (NTCDA).

This application claims the benefit of Korean Patent Application No. 10-2008-0049678, filed on May 28, 2008, in the Korean Intellectual Property Office, the entire contents of which are hereby incorporated by reference.

### BACKGROUND OF THE INVENTION

1. Field of the Invention

Disclosed herein is an organic photoelectric conversion film for an image sensor, and a photoelectric conversion device having the organic photoelectric conversion film.

2. Description of the Related Art

Photoelectric conversion devices convert light into an electrical signal using the photoelectric effect. Photoelectric conversion devices are widely used for various optical sensors for automobiles or in the home, or solar batteries, in particular for complementary metal-oxide semiconductor (CMOS) image sensors.

Photoelectric conversion films formed from an inorganic material are mainly used in commercial photoelectric conversion devices. However, since an inorganic photoelectric conversion film exhibits an inferior selectivity in relation to the wavelength of light, a CMOS image sensor using the inorganic photoelectric conversion film needs a color filter that decomposes incident light into red light, green light, and blue light. However, the use of the color filter generates a Moire defect and an optical low pass filter is therefore used to address this defect. The use of the optical filter causes degradation in the resolution of the device. As a result, research aimed at manufacturing a photoelectric conversion film using an organic material has recently been performed.

In general, a color filter, a microlens, and a photodiode are used as in commercially available photoelectric conversion devices for CMOS image sensors. This combination also produces problems in that the color filter generates a Moire defect and the compensating microlens reduces the amount of light arriving at the photodiode. To address these problems, the development of a photoelectric conversion device for a CMOS image sensor having a new structure without using the color filter, microlens, or photodiode is desirable.

FIG. 1 is a diagram of a prior art section of a commercial photoelectric conversion device for CMOS image sensors. Referring to FIG. 1, the conventional photoelectric conversion device has a structure in which a p-type material layer 12 that is a photoconductive layer, an n-type material layer 14, and a buffer layer 16 are sequentially stacked between a first electrode 10 and a second electrode 20. Here, the n-type material layer 14 is formed of tris(8-hydroxyquinolinato) aluminum (Alq₃) that is an organic material which is transparent to visible light, and the buffer layer 16, which aims to prevent an electrical short between the n-type material layer 14 and the second electrode 20, is formed of naphthalene-1,4,5,8-tetracarboxylic dianhydride (NTCDA).

### SUMMARY OF THE INVENTION

Disclosed herein is an organic photoelectric conversion film having an improved n-type material layer, and a photoelectric conversion device and an image sensor, each having the organic photoelectric conversion film.

Disclosed herein too is an organic photoelectric conversion film including a p-type material layer formed of an organic material; and an n-type material layer formed on the p-type material layer, and formed of naphthalene-1,4,5,8-tetracarboxylic dianhydride (NTCDA).

A co-deposition layer may be further formed between the p-type material layer and the n-type material layer, by co-depositing the organic material forming the p-type material layer and the NTCDA forming the n-type material layer.

The p-type material layer may be formed of at least one material selected from the group comprising phthalocyanine derivatives, triarylamine derivatives, bezidine derivatives, pyrazoline derivatives, styrylamine derivatives, hydrazine derivatives, carbazole derivatives, thiophene derivatives, pyrrole derivatives, phenanthrene derivatives, tetracence derivatives, perylene derivatives, and naphthalene derivatives.

Disclosed herein too is a photoelectric conversion device including a first electrode and a second electrode which are separated from each other; and an organic photoelectric conversion film formed between the first electrode and the second electrode, wherein the organic photoelectric conversion film includes a p-type material layer formed on the first electrode, and formed of an organic material; and an n-type material layer formed on the p-type material layer, and formed of NTCDA.

A buffer layer may be formed between the first electrode and the p-type material layer, or between the second electrode and the n-type material layer.

The first electrode may be formed of an optically transparent electrically conductive material including indium tin oxide (ITO), indium zinc oxide (IZO), zinc oxide (ZnO), and tin oxide (SnO₂). Also, the second electrode may be formed of a transparent conductive material, or a thin film metal including Al, Cu, Ti, Au, Pt, Ag, and Cr.

Disclosed herein too is an image sensor including a plurality of photoelectric conversion devices, wherein each of the plurality of photoelectric conversion devices includes a first electrode and a second electrode which are separated from each other; and an organic photoelectric conversion film formed between the first electrode and the second electrode, wherein the organic photoelectric conversion film includes a p-type material layer formed on the first electrode, and formed of an organic material; and an n-type material layer formed on the p-type material layer, and formed of NTCDA.

A plurality of photoelectric conversion devices may be stacked above and below each other on a substrate.

### BRIEF DESCRIPTION OF THE DRAWINGS

The above and other features and advantages of the present invention will become more apparent by describing in detail exemplary embodiments thereof with reference to the attached drawings in which:

FIG. 1 is an exemplary diagram of a section of a conventional photoelectric conversion device for a complementary metal-oxide semiconductor (CMOS) image sensor;

FIG. 2 is an exemplary diagram of a section of a photoelectric conversion device according to an embodiment of the present invention;

FIG. 3 is an exemplary diagram of a section of a photoelectric conversion device according to another embodiment of the present invention;

FIGS. 4A through 4C are exemplary diagrams of photoelectric conversion devices which are employed to measure a quantum efficiency according to the wavelength of light; and

FIG. 5 is a graphical representation of a photocurrent quantum efficiency versus the wavelength of light in the photoelectric conversion devices illustrated in FIGS. 4A through 4C.

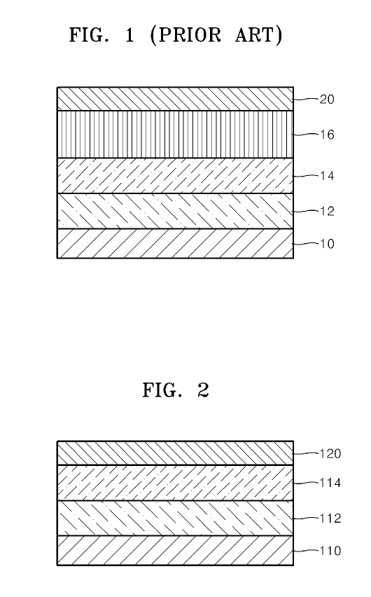

### DETAILED DESCRIPTION OF THE INVENTION

The present invention will now be described more fully with reference to the accompanying drawings, in which exemplary embodiments of the invention are shown. Like reference numerals in the drawings denote like elements. In the drawings, the thicknesses of layers and regions are exaggerated for clarity. It will also be understood that when a layer is referred to as being “on” another layer or substrate, it can be directly on the other layer or substrate, or intervening layers may also be present.

FIG. 2 is a diagram of a section of a photoelectric conversion device according to an embodiment of the present invention.

Referring to FIG. 2, the photoelectric conversion device according to the current embodiment of the present invention includes first and second electrodes 110 and 120, which are separated from each other by a predetermined distance, and an organic photoelectric conversion film, which is formed between the first electrode 110 and the second electrode 120.

The first electrode 110 may be an anode electrode. Such a first electrode 110 may be formed on a transparent substrate (not shown), which is formed of a glass or a plastic. The first electrode 110 may be formed of an optically transparent electrically conductive material. Here, examples of the transparent conductive material may be ITO, IZO, ZnO, SnO₂ or a combination comprising at least one of the foregoing transparent conductive materials. The material used for the electrode is not limited to the foregoing list of materials and other electrically conductive materials can be used. For example, a thin metal can be used as the electrode. Similarly a thin layer of an electrically conducting polymer can also be used as the electrode. Suitable examples of electrically conducting polymers are polythiophenes, polypyrrole, polyaniline, or the like, or a combination comprising at least one of the foregoing electrically conductive polymers. The second electrode 120 may be a cathode electrode, and may be formed from the aforementioned optically transparent electrically conductive material or a thin metal. In the case where the second electrode 120 is formed of the metal, the second electrode 120 may be formed to have a thickness of approximately (hereinafter, “appx.”) 15 to 20 nanometer (nm). Examples of the metal used in the electrode may be Al, Cu, Ti, Au, Pt, Ag Cr, or the like, or a combination comprising at least one of the foregoing metals, but the present invention is not limited thereto.

The organic photoelectric conversion film is formed between the first electrode 110 and the second electrode 120. The organic photoelectric conversion film converts light into an electrical signal by using a photoelectric effect. Such an organic photoelectric conversion film includes a p-type material layer 112 formed on the first electrode 110, and an n-type material layer 114 formed on the p-type material layer 112. In the current embodiment, the n-type material layer 114 is formed of naphthalene-1,4,5,8-tetracarboxylic dianhydride (NTCDA) that is a transparent organic material. Here, NTCDA that is an n-type material, generates and transports charge.

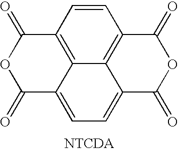

The p-type material layer 112 may be formed of phthalocyanine which can absorb light having the wavelength of visible light (appx. 550 to 700 nm).

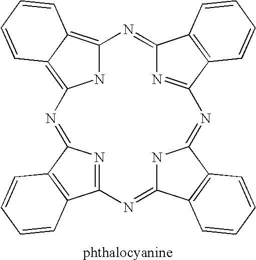

In addition to phthalocyanine, the p-type material layer 112 may be formed of at least one of phthalocyanine derivatives, triarylamine derivatives, bezidine derivatives, pyrazoline derivatives, styrylamine derivatives, hydrazine derivatives, carbazole derivatives, thiophene derivatives, pyrrole derivatives, phenanthrene derivatives, tetracence derivatives, perylene derivatives, naphthalene derivatives, or a combination comprising at least one of the foregoing, depending on the absorbing wavelength required. However, the present invention is not limited thereto, and other various materials may be used for the p-type material layer 112.

A buffer layer (not shown) may be further formed between the first electrode 110 and the p-type material layer 112, or between the second electrode 120 and the n-type material layer 114. Here, the buffer layer enables charge to be more easily transported. The buffer layer may be formed of a charge transport material (e.g., an aryl compound, and the like), which is generally used in organic light emitting diodes (OLED). The photoelectric conversion device according to the current embodiment of the present invention uses NTCDA as the n-type material, so that a quantum efficiency may be improved. A description thereof will be described later.

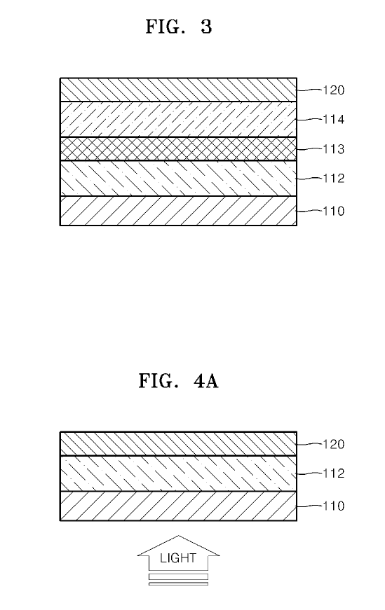

FIG. 3 is an exemplary diagram of a section of a photoelectric conversion device according to another embodiment of the present invention. Hereinafter, the current embodiment will be described, focusing on the difference between the current embodiment and the previous embodiment.

Referring to FIG. 3, the photoelectric conversion device according to the current embodiment of the present invention includes the first and second electrodes 110 and 120, which are separated from each other by the predetermined distance, and an organic photoelectric conversion film, which is formed between the first electrode 110 and the second electrode 120. Here, the organic photoelectric conversion film includes the p-type material layer 112, a co-deposition layer 113, and the n-type material layer 114, which are sequentially formed on the first electrode 110. As described above, the n-type material layer 114 is formed of NTCDA, and the p-type material layer 112 is formed of a predetermined organic material. In the current embodiment, the co-deposition layer 113 may be formed by co-depositing the n-type material (NTCDA) and the p-type material on the first electrode 110. Meanwhile, as described above, the buffer layer may be further formed between the first electrode 110 and the p-type material layer 112, or between the second electrode 120 and the n-type material layer 114.

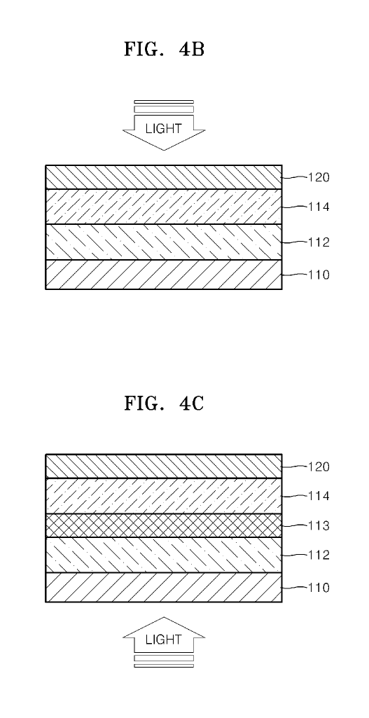

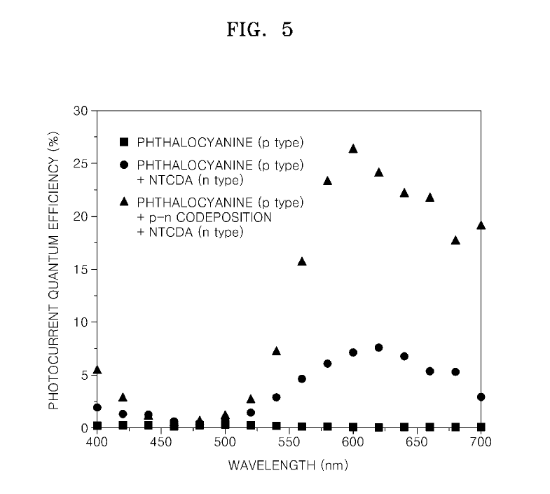

FIGS. 4A through 4C are diagrams of photoelectric conversion devices, which are employed to measure quantum efficiency according to the wavelength of light. Here, FIGS. 4B and 4C are diagrams of photoelectric conversion devices according to embodiments of the present invention. FIG. 5 is a diagram of a photocurrent quantum efficiency versus the wavelength of light in the photoelectric conversion devices illustrated in FIGS. 4A through 4C.

The photoelectric conversion device of FIG. 4A has a structure in which only the p-type material layer 112, which is formed of phthalocyanine, is formed between the first electrode 110 (an ITO electrode) and the second electrode 120 (a metal electrode). The photoelectric conversion device of FIG. 4B has a structure in which the p-type material layer 112 formed of phthalocyanine, and the n-type material layer 114 formed of NTCDA are sequentially formed between the first electrode 110 (the ITO electrode) and the second electrode 120 (the metal electrode). The photoelectric conversion device of FIG. 4C has a structure in which the p-type material 112 formed of phthalocyanine, the co-deposition layer 113 formed of phthalocyanine and NTCDA, and the n-type material layer 114 formed of NTCDA are sequentially formed between the first electrode 110 (the ITO electrode) and the second electrode 120 (the metal electrode).

The photoelectric conversion devices having the aforementioned structures were each manufactured using the following methods. First, a glass substrate on which an ITO electrode was formed is cleaned using water and ultrasonic sonication, and then cleaned using methanol and acetone. After that, oxygen plasma processing was performed on a surface of the glass substrate. After that, an organic layer (deposition speed: 2 Å/sec) (either the n-type material or the p-type material or both) and a metal electrode (deposition speed: 5 Å/sec) were successively deposited on the ITO electrode, under a 1×10⁻⁵ Torr pressure, by using a thermal evaporator. Here, NTCDA was used as the n-type material, and phthalocyanine was used as the p-type material.

In order to measure electrical features of such manufactured photoelectric conversion devices, forward bias or reverse bias was applied to the photoelectric conversion devices, when monochromatic light was irradiated on the first electrode 110 (see FIGS. 4A and 4C), and on the second electrode 120 (see FIG. 4B).

FIG. 5 is a diagram in which the photocurrent quantum efficiency versus the wavelength of light is shown for each of the photoelectric conversion devices illustrated in FIGS. 4A through 4C, when a 1 V bias voltage was applied.

Referring to FIG. 5, it is possible to see that almost no current flows in the photoelectric conversion device of FIG. 4A, which has the structure in which only the p-type material layer 112, which is formed of phthalocyanine, is formed between the first electrode 110 and the second electrode 120. However, in the photoelectric conversion device of FIG. 4B which has the structure in which the p-type material layer 112 formed of phthalocyanine and the n-type material layer 114 formed of NTCDA (the layers 112 and 114 being sequentially formed between the first electrode 110 and the second electrode 120), it is possible to see that current flows in a wavelength area of light absorbed by phthalocyanine. Also, it is possible to see that the quantum efficiency is greatly improved in the photoelectric conversion device of FIG. 4C which has the structure in which the p-type material layer 112 formed of phthalocyanine, the co-deposition layer 113 formed of phthalocyanine and NTCDA, and the n-type material layer 114 formed of NTCDA are sequentially formed between the first electrode 110 and the second electrode 120.

According to the aforementioned results, it is possible to see that the photoelectric conversion device having the improved quantum efficiency may be realized when NTCDA is used as the n-type material. Meanwhile, unlike FIGS. 4A and 4C, in FIG. 4B, light (the monochromatic light) was irradiated on the second electrode 120. However, since NTCDA is a transparent organic material, even if the light is irradiated on the first electrode 110, a similar result may be obtained.

The photoelectric conversion device described herein may be widely used for various optical sensors for automobiles or in the home, or solar batteries. In particular, it may be used for a CMOS (complementary metal-oxide semiconductor) image sensor. By applying a plurality of photoelectric conversion devices to the CMOS image sensor, high quality image can be realized. Here, the plurality of photoelectric conversion devices forming the CMOS image sensor may be stacked in a vertical direction with respect to a substrate (that is, stacked above and below each other on the substrate). For each of the plurality of photoelectric conversion devices, the p-type material capable of absorbing light in a predetermined wavelength range is used. For example, when a photoelectric conversion device, which uses phthalocyanine (that has an absorbing wavelength area of about 550 to about 700 nm) as the p-type material, is positioned below other photoelectric conversion devices, the photoelectric conversion device can be used as a pixel, which absorbs red light. In this manner, by manufacturing such a CMOS image sensor in which the plurality of photoelectric conversion devices are arranged stacked in the vertical direction, image quality with higher definition can be realized, compared to a conventional CMOS image sensor.

While this invention has been particularly shown and described with reference to exemplary embodiments thereof, it will be understood by those of ordinary skill in the art that various changes in form and details may be made therein without departing from the spirit and scope of the invention as defined by the appended claims. The exemplary embodiments should be considered in a descriptive sense only and not for purposes of limitation. Therefore, the scope of the invention is defined not by the detailed description of the invention but by the appended claims, and all differences within the scope will be construed as being included in the present invention.

What is claimed is:

1. An organic photoelectric conversion film, comprising:
a p-type material layer formed of an organic material; and
a n-type material layer formed on the p-type material layer, the n-type material layer being formed from naphthalene-1,4,5,8-tetracarboxylic dianhydride; the p-type material layer contacting the n-type material layer.

2. The organic photoelectric conversion film of claim 1, wherein a co-deposition layer is further formed between the p-type material layer and the n-type material layer, the co-deposition layer being formed by co-depositing the organic material to form the p-type material layer and the naphthalene-1,4,5,8-tetracarboxylic dianhydride to form the n-type material layer.

3. The organic photoelectric conversion film of claim 1, wherein the p-type material layer is formed of at least one material selected from the group comprising phthalocyanine derivatives, triarylamine derivatives, bezidine derivatives, pyrazoline derivatives, styrylamine derivatives, hydrazine derivatives, carbazole derivatives, thiophene derivatives, pyrrole derivatives, phenanthrene derivatives, tetracence derivatives, perylene derivatives, naphthalene derivatives, or a combination comprising at least one of the foregoing.

4. A photoelectric conversion device, comprising:
a first electrode and a second electrode which are separated from each other; and
an organic photoelectric conversion film formed between the first electrode and the second electrode and contacting the first electrode and the second electrode,
wherein the organic photoelectric conversion film comprises:
a p-type material layer formed on the first electrode, and formed from an organic material; and
a n-type material layer formed on the p-type material layer; the n-type material layer being formed from naphthalene-1,4,5,8-tetracarboxylic dianhydride.

5. The photoelectric conversion device of claim 4, wherein the organic photoelectric conversion film further comprises a co-deposition layer formed between the p-type material layer and the n-type material layer.

6. The photoelectric conversion device of claim 4, wherein the p-type material layer is selected from the group comprising phthalocyanine derivatives, triarylamine derivatives, bezidine derivatives, pyrazoline derivatives, styrylamine derivatives, hydrazine derivatives, carbazole derivatives, thiophene derivatives, pyrrole derivatives, phenanthrene derivatives, tetracence derivatives, perylene derivatives, naphthalene derivatives, or a combination comprising at least one of the foregoing.

7. The photoelectric conversion device of claim 4, wherein a buffer layer is formed between the first electrode and the p-type material layer, or between the second electrode and the n-type material layer; the buffer layer contacting the first electrode and the p-type material layer or the buffer layer contacting the second electrode and the n-type material layer.

8. The photoelectric conversion device of claim 4, wherein the first electrode is formed of a transparent conductive material.

9. The photoelectric conversion device of claim 8, wherein the transparent conductive material is indium tin oxide, indium zinc oxide, zinc oxide or tin oxide.

10. The photoelectric conversion device of claim 4, wherein the second electrode is formed of a transparent conductive material or a thin film metal.

11. The photoelectric conversion device of claim 10, wherein the metal is aluminum, copper, titanium, silver, platinum, silver, chromium, or a combination comprising at least one of the foregoing metals.

12. An image sensor, comprising:
a plurality of photoelectric conversion devices,
wherein each of the plurality of photoelectric conversion devices comprises;
a first electrode and a second electrode which are separated from each other; and
an organic photoelectric conversion film formed between the first electrode and the second electrode, the organic photoelectric conversion film contacting the first electrode and the second electrode; wherein the organic photoelectric conversion film comprises:
a p-type material layer formed on the first electrode, and formed from an organic material; and
a n-type material layer formed on the p-type material layer, and formed from naphthalene-1,4,5,8-tetracarboxylic dianhydride.

13. The image sensor of claim 12, wherein the organic photoelectric conversion film further comprises a co-deposition layer formed from the p-type material and the n-type material.

14. The image sensor of claim 12, wherein the p-type material layer is selected from the group comprising phthalocyanine derivatives, triarylamine derivatives, bezidine derivatives, pyrazoline derivatives, styrylamine derivatives, hydrazine derivatives, carbazole derivatives, thiophene derivatives, pyrrole derivatives, phenanthrene derivatives, tetracence derivatives, perylene derivatives, naphthalene derivatives, or a combination comprising at least one of the foregoing.

15. The image sensor of claim 12, wherein a buffer layer is formed between the first electrode and the p-type material layer, or between the second electrode and the n-type material layer; the buffer layer contacting the first electrode and the p-type material layer or the buffer layer contacting the second electrode and the n-type material layer.

16. The image sensor of claim 12, wherein the plurality of photoelectric conversion devices are stacked above and below each other on a substrate.
